(19) United States
(12) Patent Application Publication
(10) Pub. No.: US 2018/0263138 A1
(43) Pub. Date: Sep. 13, 2018

(54) SIPHON-TYPE HEAT DISSIPATION DEVICE AND DISPLAY DEVICE WITH SAME

(71) Applicant: AURAS Technology Co., Ltd., New Taipei City (TW)

(72) Inventors: AN-CHIH WU, New Taipei City (TW); Mu-Shu Fan, New Taipei City (TW); Chien-Yu Chen, New Taipei City (TW)

(21) Appl. No.: 15/473,947

(22) Filed: Mar. 30, 2017

(30) Foreign Application Priority Data
Mar. 10, 2017 (TW) 106108003

(51) Int. Cl. H05K 7/20; F28F 3/12; F28F 13/00; F28F 3/02; F28F 9/007

(52) U.S. Cl. CPC H05K 7/2099; F28F 3/12; F28F 13/003; F28F 3/022; H05K 7/20963; H05K 7/20336; H05K 7/20481; F28F 2225/04; H05K 7/20972; F28F 9/0075

(57) ABSTRACT

A siphon-type heat dissipation device includes a first plate body, a second plate body and a working liquid. An accommodation space is formed between the first plate body and the second plate body. The working liquid is accumulated in a lower portion of the accommodation space. A heat source is attached on the siphon-type heat dissipation device. After a heat energy generated by the heat source is transferred into the working liquid, the heat energy is absorbed by the working liquid, so that a portion of the working liquid is vaporized into a working vapor. After the working vapor ascends to an upper portion of the accommodation space, the heat energy is dissipated to surroundings, and the working vapor is condensed and changed into the working liquid. The working liquid flows back to the lower portion of the accommodation space.

### FIELD OF THE INVENTION

The present invention relates to a heat dissipation plate, and more particularly to a siphon-type heat dissipation device for an electronic device and a display device with the siphon-type heat dissipation device.

### BACKGROUND OF THE INVENTION

Nowadays, an electronic display device such as a LCD TV or a large-sized screen is usually equipped with a display panel and a heat source. For example, the heat source is a light-emitting element, a light bar or a light emitting diode. When a light beam generated by the heat source is projected to the display panel, an image is shown on the display panel. Since the heat source continuously emits the light beam, a large amount of heat energy is also generated. Generally, the electronic display device is equipped with a heat dissipation device to dissipate the heat energy away. If the heat energy is not effectively removed, the light-emitting element or other component of the electronic display device is possibly damaged because of the overheated condition.

Conventionally, the heat dissipation device for the electronic display device includes a heat dissipation plate or a thermally conductive plate. The heat dissipation plate or the thermally conductive plate is attached on the heat source. Moreover, the electronic display device comprises a heat dissipation region (e.g., a ventilation hole in a casing of the television). After the heat energy generated by the heat source is transferred to the heat dissipation region through the heat dissipation plate or the thermally conductive plate, the heat energy is exhausted to the surroundings through the heat dissipation region. The heat dissipation plate or the thermally conductive plate of the conventional technology is able to transfer heat energy to the surroundings and assist in exhausting heat energy. However, the heat dissipating function of the conventional heat dissipation plate or thermally conductive plate is usually unsatisfied. In case that a large amount of heat energy is generated by a large-sized screen or a great number of heat sources, the heat dissipation efficiency of the conventional heat dissipation plate or thermally conductive plate is insufficient.

In other words, the conventional technology needs to be further improved.

### SUMMARY OF THE INVENTION

For solving the drawbacks of the conventional technology, the present invention provides a siphon-type heat dissipation device and a display device with the siphon-type heat dissipation device. The siphon-type heat dissipation device has good heat-conducting efficacy and good heat-dissipating efficacy. The siphon-type heat dissipation device is capable of absorbing the heat energy from the heat source and directly conducting and dissipating the heat energy. Consequently, the heat dissipating efficiency is enhanced.

In accordance with an aspect of the present invention, there is provided a siphon-type heat dissipation device. The siphon-type heat dissipation device includes a first plate body, a second plate body and a working liquid. The first plate body has the first inner surface and a first external surface. The second plate body has a second inner surface and a second external surface. The first inner surface and the second inner surface are opposed to and separated from each other. The first plate body and the second plate body are partially attached on each other. An accommodation space is formed between the first inner surface and the second inner surface. The accommodation space includes an upper portion and a lower portion. The working liquid is contained within the accommodation space and accumulated in the lower portion of the accommodation space along a gravity direction. A heat source is attached on the siphon-type heat dissipation device and contacted with the first external surface or the second external surface. The heat source is aligned with the lower portion of the accommodation space. After a heat energy generated by the heat source is transferred into the accommodation space through the first external surface or the second external surface, the heat energy is absorbed by the working liquid, so that a portion of the working liquid is vaporized into a working vapor. After the working vapor ascends to the upper portion of the accommodation space, the heat energy is dissipated to surroundings, the working vapor is condensed and changed into the working liquid, and the working liquid contacts with the first inner surface and the second inner surface and flows back to the lower portion of the accommodation space along the gravity direction.

In an embodiment, the siphon-type heat dissipation device further includes a boiling enhancement structure. The boiling enhancement structure is disposed within the lower portion of the accommodation space and immersed in the working liquid. When the heat energy is transferred to the working liquid within the lower portion of the accommodation space through the boiling enhancement structure, the heat energy is absorbed by the working liquid, so that the working liquid is vaporized into the working vapor and the working vapor ascends to the upper portion of the accommodation space.

In an embodiment, the boiling enhancement structure is contacted with the first inner surface and/or the second inner surface, and the boiling enhancement structure is selected from a metallic foam structure, a woven wire cloth or a powder metallurgy structure.

In an embodiment, the heat source includes a heat transfer surface. The heat transfer surface is attached on the first external surface or the second external surface along an attaching direction. The attaching direction is perpendicular to the gravity direction.

In an embodiment, the heat source includes a heat conduction substrate, and the heat conduction substrate is attached on the first external surface or the second external surface.

In an embodiment, the heat conduction substrate is attached on the first external surface or the second external surface along an attaching direction. The attaching direction is perpendicular to the gravity direction.

In an embodiment, the siphon-type heat dissipation device further includes a heat dissipation enhancement element. The heat dissipation enhancement element is disposed on the first external surface and/or the second external surface and aligned with the upper portion of the accommodation space.

In an embodiment, the heat dissipation enhancement element is a fin-type heat sink, a fan or a heat pipe.

In an embodiment, the siphon-type heat dissipation device further includes a supporting structure. The supporting structure is disposed within the accommodation space and contacted with the first inner surface and the second inner surface.

In an embodiment, the supporting structure is protruded from the second inner surface of the second plate body toward the first plate body and connected with the first inner surface of the first plate body.

In an embodiment, the supporting structure is a wavy plate. The wavy plate is disposed within the accommodation space and connected with the first inner surface and the second inner surface.

In an embodiment, the first plate body and the second plate body are made of different materials, and the first plate body and the second plate body are made of copper, aluminum or stainless steel.

In an embodiment, the heat source is a light source selected from a light emitting diode, a light bar or a light bulb.

In an embodiment, a volume of the working liquid accounts for 50% to 98% of a capacity of the accommodation space.

In accordance with another aspect of the present invention, there is provided a display device, a siphon-type heat dissipation device and a heat source. The siphon-type heat dissipation device is located near the display panel and includes a first inner surface, a second inner surface and a working liquid. The first inner surface and the second inner surface are opposed to and separated from each other. An accommodation space is formed between the first inner surface and the second inner surface. The accommodation space includes an upper portion and a lower portion. The working liquid is contained within the accommodation space and accumulated in the lower portion of the accommodation space along a gravity direction. The heat source is arranged between the display panel and the siphon-type heat dissipation device, attached on the siphon-type heat dissipation device, and aligned with the lower portion of the accommodation space. The heat source generates a light beam and a heat energy, and an image is shown on the display panel when the light beam is projected to the display panel. After the heat energy is transferred into the accommodation space through the siphon-type heat dissipation device, the heat energy is absorbed by the working liquid, so that a portion of the working liquid is vaporized into a working vapor. After the working vapor ascends to the upper portion of the accommodation space, the heat energy is dissipated to surroundings, the working vapor is condensed and changed into the working liquid, and the working liquid contacts with the first inner surface and the second inner surface and flows back to the lower portion of the accommodation space along the gravity direction.

In an embodiment, the siphon-type heat dissipation device is in parallel with the display panel.

In an embodiment, the siphon-type heat dissipation device further includes a boiling enhancement structure. The boiling enhancement structure is disposed within the lower portion of the accommodation space and immersed in the working liquid. When the heat energy is transferred to the working liquid within the lower portion of the accommodation space through the boiling enhancement structure, the heat energy is absorbed by the working liquid, so that the working liquid is vaporized into the working vapor and the working vapor ascends to the upper portion of the accommodation space.

In an embodiment, the boiling enhancement structure is contacted with the first inner surface and/or the second inner surface, and the boiling enhancement structure is selected from a metallic foam structure, a woven wire cloth or a powder metallurgy structure.

In an embodiment, the siphon-type heat dissipation device further includes a first external surface and a second external surface. The heat source is attached on the first external surface or the second external surface, and the heat energy is transferred into the accommodation space through the first external surface or the second external surface.

In an embodiment, the siphon-type heat dissipation device further includes a heat dissipation enhancement element. The heat dissipation enhancement element is disposed on the first external surface and/or the second external surface and aligned with the upper portion of the accommodation space.

In an embodiment, the heat dissipation enhancement element is a fin-type heat sink, a fan or a heat pipe.

In an embodiment, the heat source includes a heat transfer surface, and the heat transfer surface is attached on the first external surface or the second external surface along an attaching direction, wherein the attaching direction is perpendicular to the gravity direction.

In an embodiment, the heat source includes a heat conduction substrate, and the heat conduction substrate is attached on the first external surface or the second external surface along an attaching direction, wherein the attaching direction is perpendicular to the gravity direction.

In an embodiment, the siphon-type heat dissipation device further comprises a supporting structure. The supporting structure is disposed within the accommodation space and contacted with the first inner surface and the second inner surface.

In an embodiment, the supporting structure is protruded from the second inner surface toward the first inner surface and connected with the first inner surface.

In an embodiment, the supporting structure is a wavy plate. The wavy plate is disposed within the accommodation space and connected with the first inner surface and the second inner surface.

In an embodiment, the siphon-type heat dissipation device further includes a first plate body and a second plate body. The first inner surface is formed on the first plate body. The second inner surface is formed on the second plate body. The first plate body and the second plate body are partially attached on each other, so that the accommodation space is formed between the first inner surface and the second inner surface. The first plate body and the second plate body are made of different materials. The first plate body and the second plate body are made of copper, aluminum or stainless steel.

In an embodiment, the heat source is a light source selected from a light emitting diode, a light bar or a light bulb.

In an embodiment, a volume of the working liquid accounts for 50% to 98% of a capacity of the accommodation space.

From the above descriptions, the siphon-type heat dissipation device has good heat-conducting efficacy and good heat-dissipating efficacy. The siphon-type heat dissipation device is capable of absorbing the heat energy from the heat source and directly conducting and dissipating the heat energy. Consequently, the heat dissipating efficiency is enhanced. In case that a large amount of heat energy is generated by a large-sized screen or a great number of heat sources, the siphon-type heat dissipation device is effective to dissipate the heat energy away. In other words, the siphon-type heat dissipation device of the present invention can solve the drawbacks of the conventional technologies.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective and exploded view illustrating a display device according to a first embodiment of the present invention;

FIG. 2 is a schematic cross-sectional view illustrating the display device according to the first embodiment of the present invention;

FIG. 3 is a schematic perspective view illustrating the siphon-type heat dissipation device and the heat source of the display device according to the first embodiment of the present invention;

FIG. 4 is a schematic perspective and exploded view illustrating the siphon-type heat dissipation device and the heat source of the display device according to the first embodiment of the present invention;

FIG. 5 is a schematic cross-sectional view illustrating the heat-dissipating process of the siphon-type heat dissipation device and the heat source of the display device according to the first embodiment of the present invention;

FIG. 6 is a schematic perspective and exploded view illustrating a siphon-type heat dissipation device according to a second embodiment of the present invention;

FIG. 7 is a schematic cross-sectional view illustrating the heat-dissipating process of the siphon-type heat dissipation device according to the second embodiment of the present invention;

FIG. 8 is a schematic perspective and exploded view illustrating a siphon-type heat dissipation device according to a third embodiment of the present invention;

FIG. 9 is a schematic cross-sectional view illustrating the heat-dissipating process of the siphon-type heat dissipation device according to the third embodiment of the present invention;

FIG. 10 is a schematic perspective and exploded view illustrating a siphon-type heat dissipation device according to a fourth embodiment of the present invention;

FIG. 11 is a schematic cross-sectional view illustrating the heat-dissipating process of the siphon-type heat dissipation device according to the fourth embodiment of the present invention;

FIG. 12 is a schematic perspective and exploded view illustrating a siphon-type heat dissipation device according to a fifth embodiment of the present invention; and

FIG. 13 is a schematic cross-sectional view illustrating the heat-dissipating process of the siphon-type heat dissipation device according to the fifth embodiment of the present invention.

### DETAILED DESCRIPTION OF THE PREFERRED EMBODIMENT

The present invention will now be described more specifically with reference to the following embodiments and accompanying drawings.

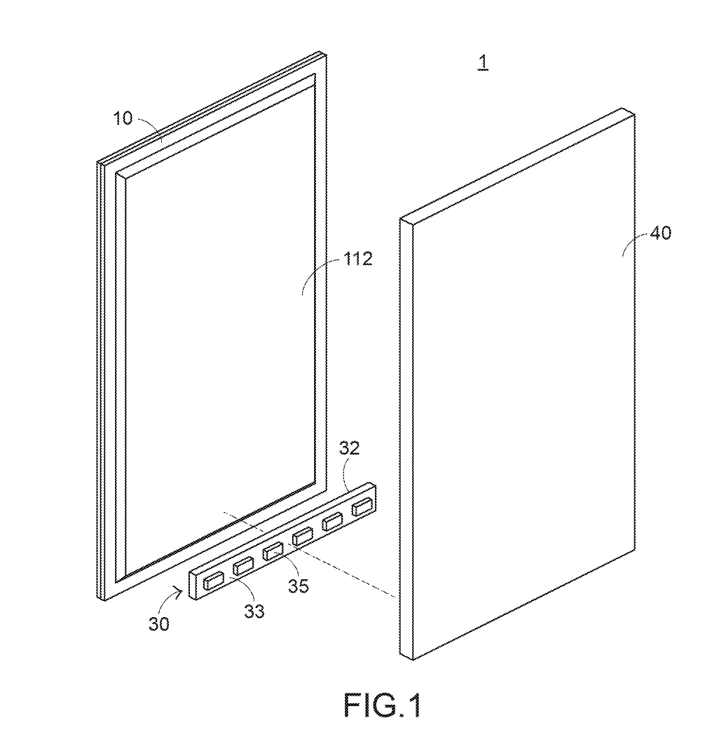

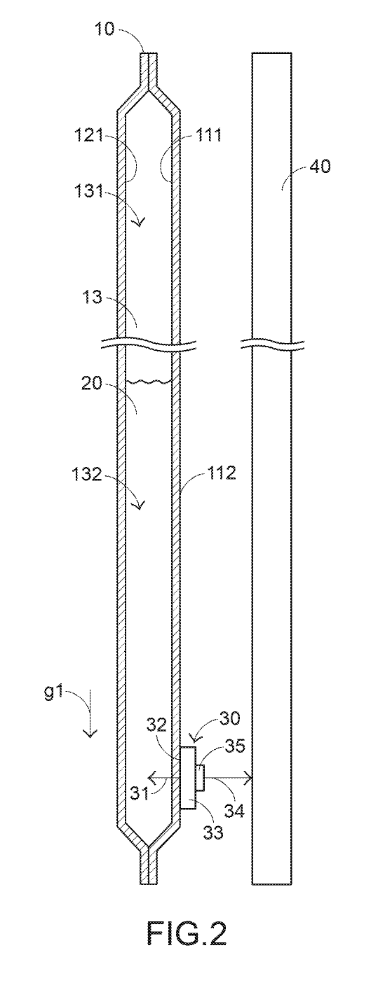

A first embodiment of the present invention will be described as follows. FIG. 1 is a schematic perspective and exploded view illustrating a display device according to a first embodiment of the present invention. FIG. 2 is a schematic cross-sectional view illustrating the display device according to the first embodiment of the present invention. The display device 1 comprises a display panel 40, a siphon-type heat dissipation device 10 and a heat source 30. The siphon-type heat dissipation device 10 comprises a first inner surface 111 and a second inner surface 121, and contains a working liquid 20. An accommodation space 13 is formed between the first inner surface 111 and the second inner surface 121. The accommodation space 13 comprises an upper portion 131 and a lower portion 132. The heat source 30 comprises a heat transfer surface 32, a heat conduction substrate 33 and a light-emitting element 35. The heat transfer surface 32 is formed on the heat conduction substrate 33. The light-emitting element 35 is disposed on the heat conduction substrate 33. The siphon-type heat dissipation device 10 is located near the display panel 40. Moreover, the siphon-type heat dissipation device 10 is in parallel with the display panel 40. The working liquid 20 is contained within the accommodation space 13. Moreover, the working liquid 20 is accumulated in the lower portion 132 of the accommodation space 13 along a gravity direction g1. The heat source 30 is arranged between the siphon-type heat dissipation device 10 and the display panel 40. Moreover, the heat source 30 is aligned with the lower portion 132 of the accommodation space 13. The heat transfer surface 32 of the heat source 30 is attached on the siphon-type heat dissipation device 10. The light-emitting element 35 faces the display panel 40. Moreover, the light-emitting element 35 of the heat source 30 generates a light beam 34 and generates heat energy 31. The light beam 34 is projected to the display panel 40, and thus an image is shown on the display panel 40. The heat energy 31 is transferred to the accommodation space 13 of the siphon-type heat dissipation device 10 through the heat conduction substrate 33 and the heat transfer surface 32 so as to be dissipated away.

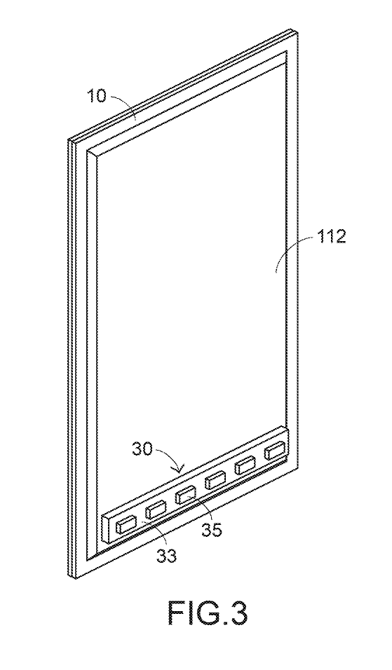

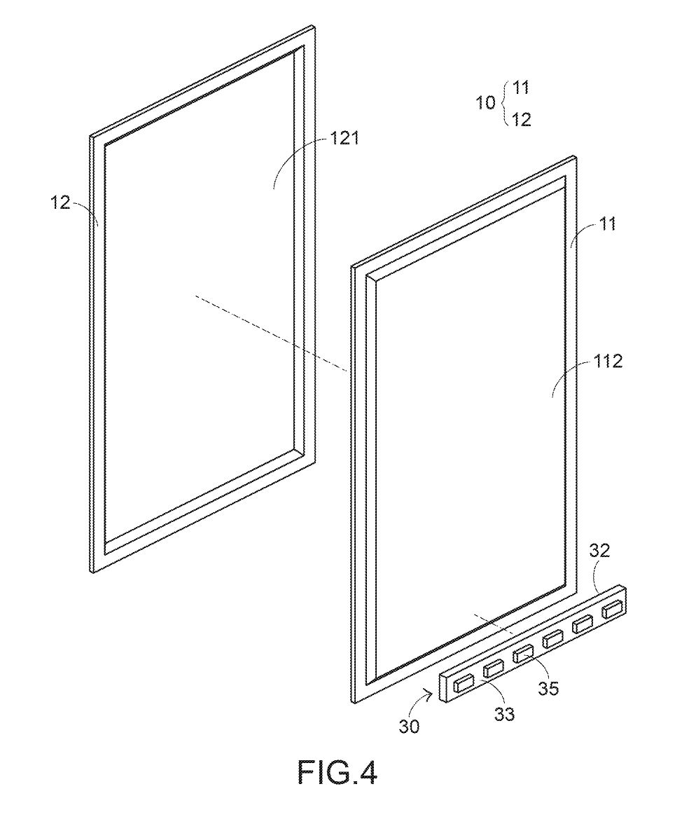

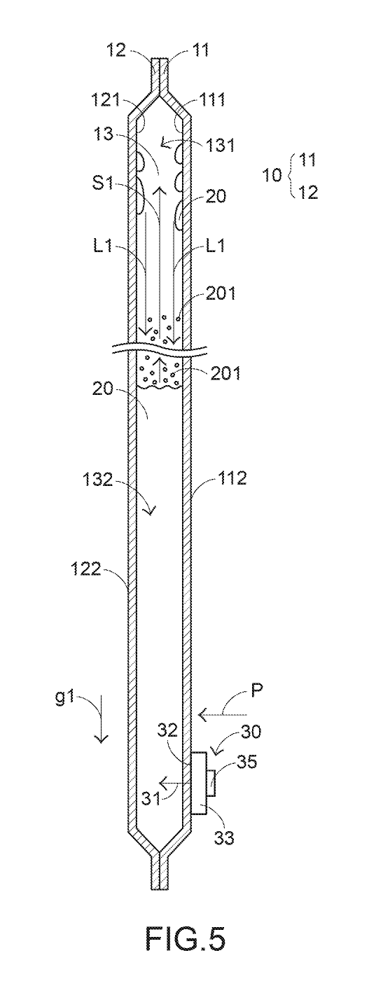

The detailed structure and the heat-dissipating process of the siphon-type heat dissipation device 10 will be described as follows. FIG. 3 is a schematic perspective view illustrating the siphon-type heat dissipation device and the heat source of the display device according to the first embodiment of the present invention. FIG. 4 is a schematic perspective and exploded view illustrating the siphon-type heat dissipation device and the heat source of the display device according to the first embodiment of the present invention. FIG. 5 is a schematic cross-sectional view illustrating the heat-dissipating process of the siphon-type heat dissipation device and the heat source of the display device according to the first embodiment of the present invention.

The siphon-type heat dissipation device 10 comprises a first plate body 11 and a second plate body 12. The first plate body 11 has the first inner surface 111 and a first external surface 112. The second plate body 12 has the second inner surface 121 and a second external surface 122. The outer periphery of the first plate body 11 and the outer periphery of the second plate body 12 are partially attached on each other. The first inner surface 111 and the second inner surface 121 are opposed to and separated from each other. Consequently, the accommodation space 13 is formed between the first inner surface 111 and the second inner surface 121. The heat source 30 is attached on the first external surface 112 or the second external surface 122. In this embodiment, the heat source 30 is attached on the first external surface 112.

The heat conduction substrate 33 and the heat transfer surface 32 of the heat source 30 are attached on the first external surface 112 of the first plate body 11 along an attaching direction P. The attaching direction P is perpendicular to the gravity direction g1. The heat energy 31 is transferred into the accommodation space 13 of the siphon-type heat dissipation device 10 through the first external surface 112 of the first plate body 11. After the heat energy 31 is absorbed by the working liquid 20, a portion of the working liquid 20 is vaporized into working vapor 201. Since the working liquid 20 is vaporized into working vapor 201 through heat absorption, the working vapor 201 ascends. That is, the working vapor 201 ascends from the lower portion 132 of the accommodation space 13 to the upper portion 131 of the accommodation space 13 along a vaporizing direction S1. After the heat energy 31 is exhausted from the upper portion 131 of the accommodation space 13 to the surroundings, the working vapor 201 is condensed and changed into the working liquid 20 because the heat energy 31 is dissipated away. As known, liquid flows along the gravity direction. Consequently, the working liquid 20 flows downwardly to the lower portion 132 of the accommodation space 13 along a backflow direction L1 while contacting with the first inner surface 111 and the second inner surface 121. The backflow direction L1 is identical to the gravity direction g1.

In an embodiment, the volume of the working liquid 20 accounts for 50% to 98% of the capacity of the accommodation space 13. The first plate body 11 and the second plate body 12 are made of different materials. For example, the first plate body 11 and the second plate body 12 are made of copper, aluminum, stainless steel or any other appropriate material. The heat source 30 is a light source selected from a light emitting diode, a light bar or a light bulb.

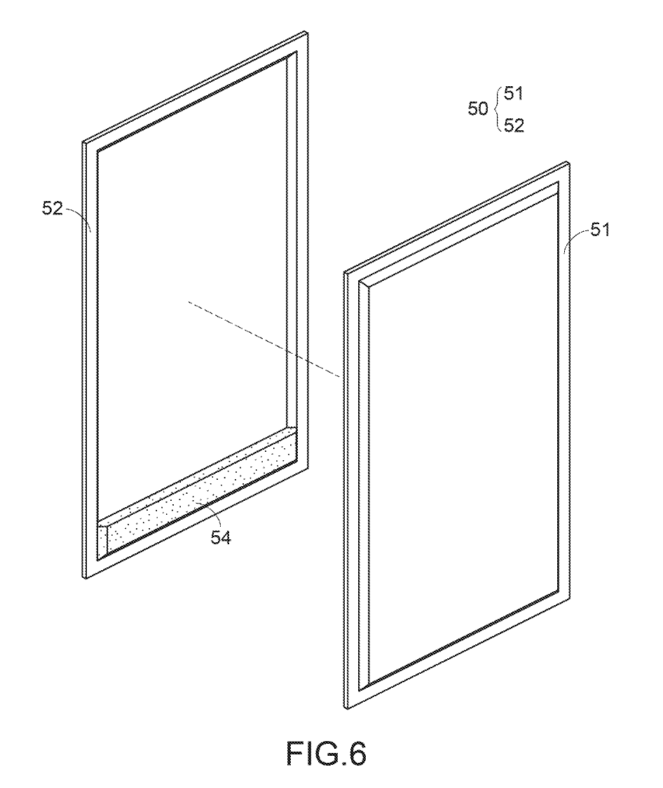

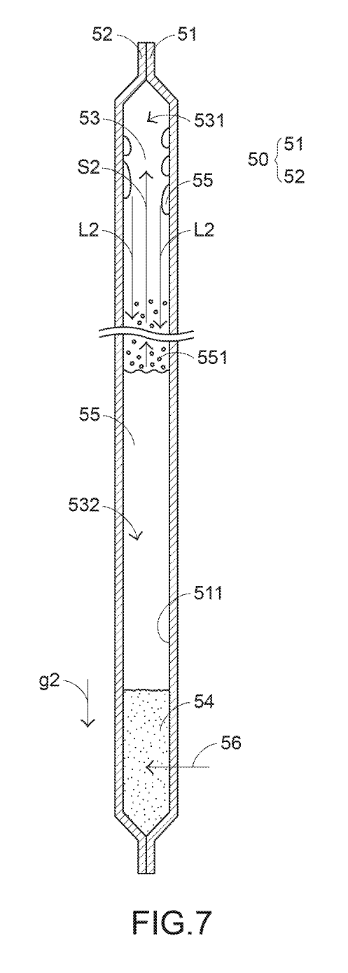

A second embodiment of the present invention will be described as follows. FIG. 6 is a schematic perspective and exploded view illustrating a siphon-type heat dissipation device according to a second embodiment of the present invention. FIG. 7 is a schematic cross-sectional view illustrating the heat-dissipating process of the siphon-type heat dissipation device according to the second embodiment of the present invention. The structures and operations of some components of this embodiment that are similar to those of the first embodiment are not redundantly described herein.

In this embodiment, the siphon-type heat dissipation device 50 comprises a first plate body 51, a second plate body 52, a working liquid 55 and a boiling enhancement structure 54. The first plate body 51 and the second plate body 52 are partially attached on each other. Consequently, an accommodation space 53 is formed between the first plate body 51 and the second plate body 52. The accommodation space 53 comprises an upper portion 531 and a lower portion 532. Moreover, the working liquid 55 is accumulated in the lower portion 532 of the accommodation space 53 along a gravity direction g2. The boiling enhancement structure 54 is disposed within the lower portion 532 of the accommodation space 53 and immersed in the working liquid 55. The boiling enhancement structure 54 is a porous tissue structure. Moreover, the boiling enhancement structure 54 is contacted with the first plate body 51 and/or the second plate body 52. In this embodiment, the boiling enhancement structure 54 is disposed on the second plate body 52 and contacted with the first inner surface 511 of the first plate body 51. After the heat energy 56 is transferred into the accommodation space 53 through the first inner surface 511, the heat energy 56 is transferred to the boiling enhancement structure 54. Since the boiling enhancement structure 54 is immersed in the working liquid 55, the pores inside the boiling enhancement structure 54 are well contacted with the working liquid 55. In such way, the total area for transferring the heat energy 56 is increased, the heat energy 56 is transferred to the working liquid 55 at a faster rate, and the working liquid 55 is vaporized into the working vapor 551 more quickly. The working vapor 551 ascends along a vaporizing direction S2. After the heat energy 56 is exhausted from the upper portion 531 of the accommodation space 53 to the surroundings, the working vapor 551 is condensed and changed into the working liquid 55. Consequently, the working liquid 55 flows downwardly to the lower portion 532 of the accommodation space 53 along a backflow direction L2. Preferably, the boiling enhancement structure 54 is a metallic foam structure, a woven wire cloth or a powder metallurgy structure.

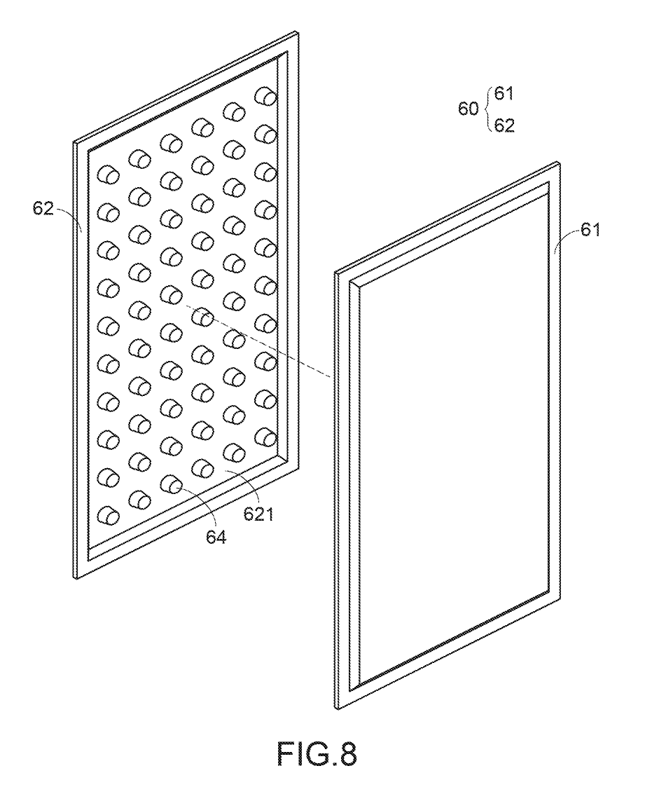

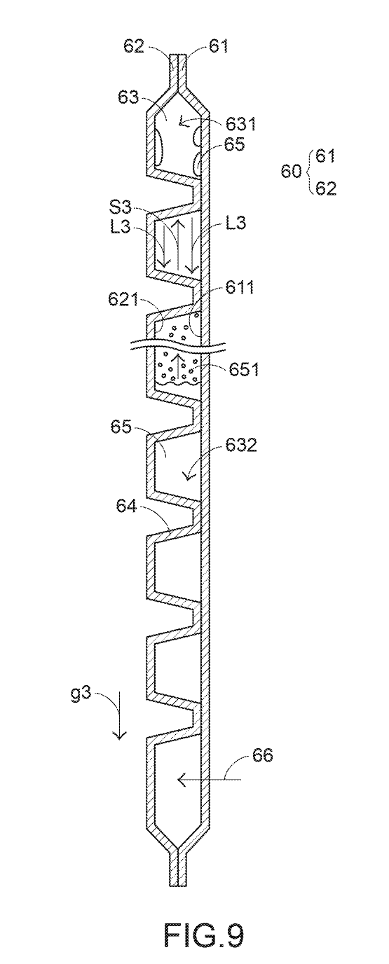

A third embodiment of the present invention will be described as follows. FIG. 8 is a schematic perspective and exploded view illustrating a siphon-type heat dissipation device according to a third embodiment of the present invention. FIG. 9 is a schematic cross-sectional view illustrating the heat-dissipating process of the siphon-type heat dissipation device according to the third embodiment of the present invention. The structures and operations of some components of this embodiment that are similar to those of the first embodiment are not redundantly described herein.

In this embodiment, the siphon-type heat dissipation device 60 comprises a first plate body 61, a second plate body 62, a working liquid 65 and a supporting structure 64. The first plate body 61 and the second plate body 62 are partially attached on each other. Consequently, an accommodation space 63 is formed between the first plate body 61 and the second plate body 62. The accommodation space 63 comprises an upper portion 631 and a lower portion 632. Moreover, the working liquid 65 is contained within the accommodation space 63 and accumulated in the lower portion 632 of the accommodation space 63 along a gravity direction g3. The supporting structure 64 is disposed within the accommodation space 63 and contacted with a first inner surface 611 of the first plate body 61 and a second inner surface 621 of the second plate body 62. In an embodiment, the supporting structure 64 is a protrusion post. The protrusion post is protruded from the second inner surface 621 of the second plate body 62 toward the first plate body 61 and connected with the first inner surface 611 of the first plate body 61. Since the supporting structure 64 is disposed within the accommodation space 63, the combination of the first plate body 61 and the second plate body 62 is strengthened and not readily subjected to deformation. Moreover, the supporting structure 64 is helpful to maintain the unobstructed state of the accommodation space 63. After the heat energy 66 is transferred into the lower portion 632 of the accommodation space 63, the heat energy 66 is absorbed by the working liquid 65. Consequently, a portion of the working liquid 65 is vaporized into working vapor 651. The working vapor 651 ascends to the upper portion 631 of the accommodation space 63 along a vaporizing direction S3. After the working vapor 651 is condensed and changed into the working liquid 65, the working liquid 65 flows downwardly to the lower portion 632 of the accommodation space 63 along a backflow direction L3. Consequently, the working liquid 65 is accumulated in the lower portion 632 of the accommodation space 63.

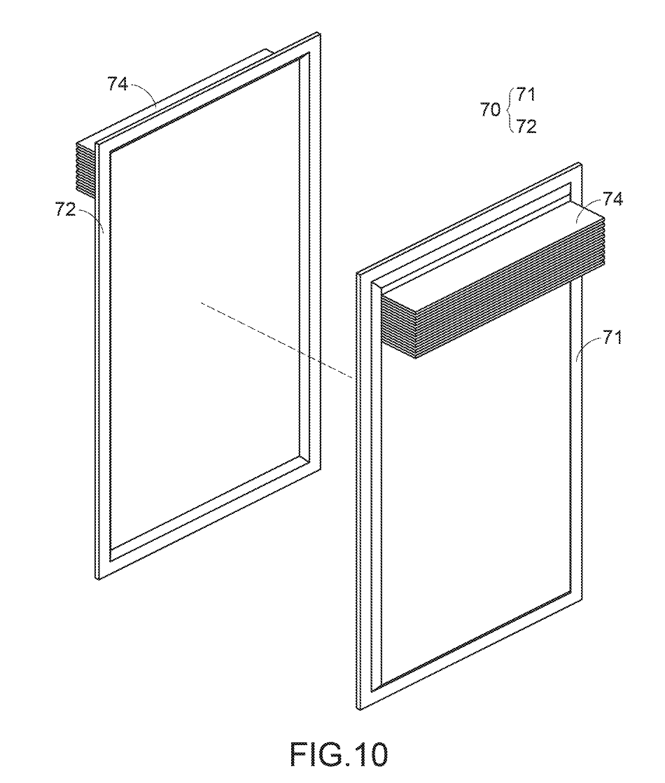

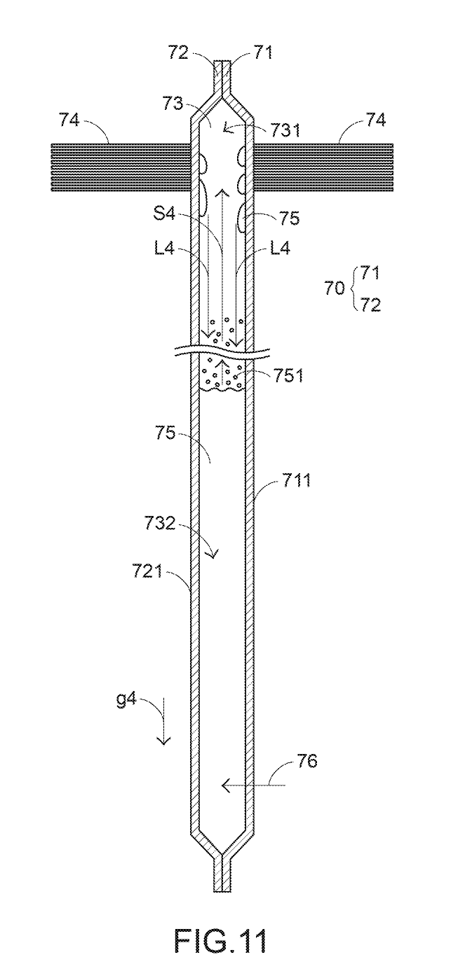

A fourth embodiment of the present invention will be described as follows. FIG. 10 is a schematic perspective and exploded view illustrating a siphon-type heat dissipation device according to a fourth embodiment of the present invention. FIG. 11 is a schematic cross-sectional view illustrating the heat-dissipating process of the siphon-type heat dissipation device according to the fourth embodiment of the present invention. The structures and operations of some components of this embodiment that are similar to those of the first embodiment are not redundantly described herein.

In this embodiment, the siphon-type heat dissipation device 70 comprises a first plate body 71, a second plate body 72, a working liquid 75 and a heat dissipation enhancement element 74. The first plate body 71 and the second plate body 72 are partially attached on each other. Consequently, an accommodation space 73 is formed between the first plate body 71 and the second plate body 72. The accommodation space 73 comprises an upper portion 731 and a lower portion 732. The first plate body 71 has a first external surface 711. The second plate body 72 has a second external surface 721. The heat dissipation enhancement element 74 is disposed on the first external surface 711 and/or the second external surface 721. Moreover, the heat dissipation enhancement element 74 is aligned with the upper portion 731 of the accommodation space 73. Moreover, the working liquid 75 is contained within the accommodation space 73 and accumulated in the lower portion 732 of the accommodation space 73 along a gravity direction g4. After the heat energy 77 is transferred into the lower portion 732 of the accommodation space 73, the heat energy 77 is absorbed by the working liquid 75. Consequently, a portion of the working liquid 75 is vaporized into working vapor 751. The working vapor 751 ascends to the upper portion 731 of the accommodation space 73 along a vaporizing direction S4. The heat dissipation enhancement element 74 corresponding to the upper portion 731 of the accommodation space 73 assists in dissipating the heat energy 76 to the surroundings. Consequently, the working vapor 751 is condensed and changed into the working liquid 75 more quickly. The working liquid 75 flows downwardly to the lower portion 732 of the accommodation space 73 along a backflow direction L4. Consequently, the working liquid 75 is accumulated in the lower portion 732 of the accommodation space 73. In other words, the use of the heat dissipation enhancement element 74 can increase the heat dissipating efficacy. An example of the heat dissipation enhancement element 74 includes but is not limited to a fin-type heat sink, a fan or a heat pipe.

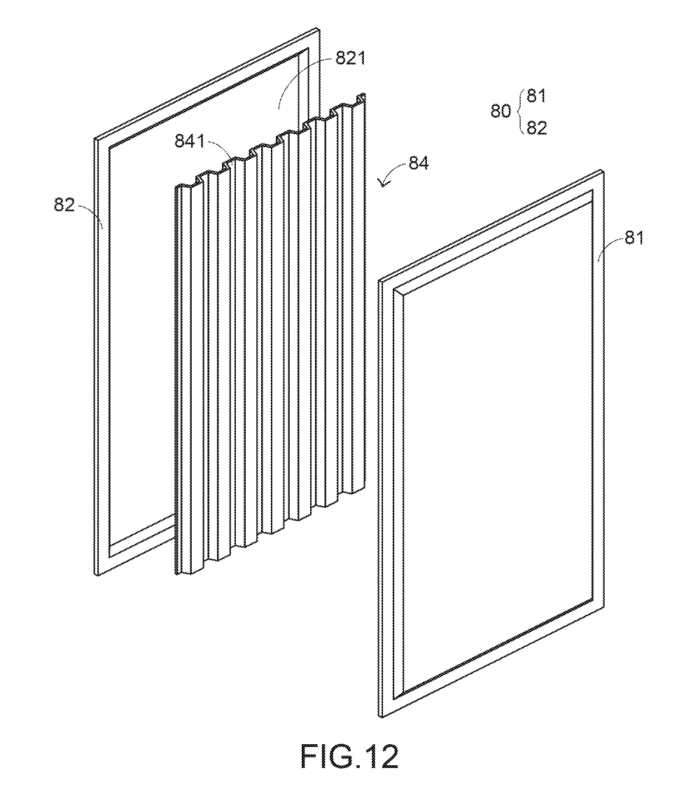

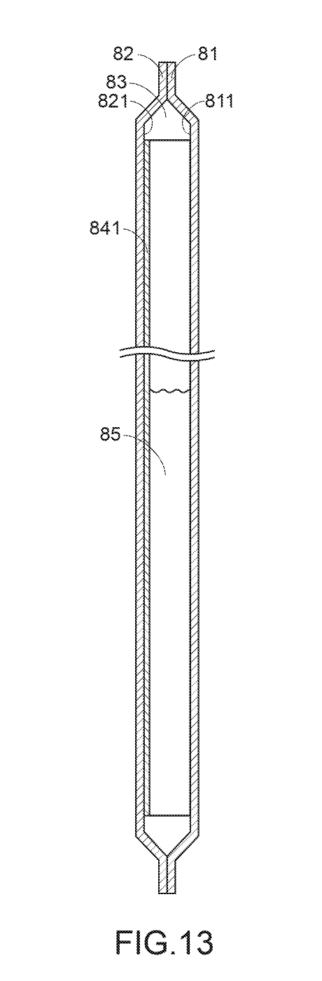

A fifth embodiment of the present invention will be described as follows. FIG. 12 is a schematic perspective and exploded view illustrating a siphon-type heat dissipation device according to a fifth embodiment of the present invention. FIG. 13 is a schematic cross-sectional view illustrating the heat-dissipating process of the siphon-type heat dissipation device according to the fifth embodiment of the present invention. The structures and operations of some components of this embodiment that are similar to those of the first embodiment are not redundantly described herein.

In this embodiment, the siphon-type heat dissipation device 60 comprises a first plate body 81, a second plate body 82, a working liquid 85 and a supporting structure 84. The first plate body 81 has a first inner surface 811. The second plate body 82 has a second inner surface 821. The first plate body 81 and the second plate body 82 are partially attached on each other. Consequently, an accommodation space 83 is formed between the first inner surface 811 and the second inner surface 821. The working liquid 85 is contained within the accommodation space 83. Moreover, the supporting structure 84 is a wavy plate 841. The wavy plate 841 is disposed within the accommodation space 83 and partially immersed in the working liquid 85. A part of the wavy plate 841 is connected with the first inner surface 811 and the second inner surface 821. Since the wavy plate 841 is disposed within the accommodation space 83, the combination of the first plate body 81 and the second plate body 82 is strengthened and not readily subjected to deformation. Moreover, the wavy plate 841 is helpful to maintain the unobstructed state of the accommodation space 83. The heat-dissipating process and the operations of the working liquid 85 are similar to those of the first embodiment, and are not redundantly described herein.

From the above descriptions, the present invention provides the siphon-type heat dissipation device. The siphon-type heat dissipation device has good heat-dissipating efficacy. The siphon-type heat dissipation device is capable of absorbing the heat energy from the heat source and directly conducting and dissipating the heat energy. Consequently, the heat dissipating efficiency is enhanced. In case that a large amount of heat energy is generated by a large-sized screen or a great number of heat sources, the siphon-type heat dissipation device is effective to dissipate the heat energy away. In other words, the siphon-type heat dissipation device of the present invention can solve the drawbacks of the conventional technologies.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A siphon-type heat dissipation device, comprising:
a first plate body having the first inner surface and a first external surface;
a second plate body having a second inner surface and a second external surface, wherein the first inner surface and the second inner surface are opposed to and separated from each other, the first plate body and the second plate body are partially attached on each other, an accommodation space is formed between the first inner surface and the second inner surface, and the accommodation space comprises an upper portion and a lower portion; and
a working liquid contained within the accommodation space and accumulated in the lower portion of the accommodation space along a gravity direction,
wherein a heat source is attached on the siphon-type heat dissipation device and contacted with the first external surface or the second external surface, and the heat source is aligned with the lower portion of the accommodation space, wherein after a heat energy generated by the heat source is transferred into the accommodation space through the first external surface or the second external surface, the heat energy is absorbed by the working liquid, so that a portion of the working liquid is vaporized into a working vapor, wherein after the working vapor ascends to the upper portion of the accommodation space, the heat energy is dissipated to surroundings, the working vapor is condensed and changed into the working liquid, and the working liquid contacts with the first inner surface and the second inner surface and flows back to the lower portion of the accommodation space along the gravity direction.

2. The siphon-type heat dissipation device according to claim 1, further comprising a boiling enhancement structure, wherein the boiling enhancement structure is disposed within the lower portion of the accommodation space and immersed in the working liquid, wherein when the heat energy is transferred to the working liquid within the lower portion of the accommodation space through the boiling enhancement structure, the heat energy is absorbed by the working liquid, so that the working liquid is vaporized into the working vapor and the working vapor ascends to the upper portion of the accommodation space.

3. The siphon-type heat dissipation device according to claim 2, wherein the boiling enhancement structure is contacted with the first inner surface and/or the second inner surface, and the boiling enhancement structure is selected from a metallic foam structure, a woven wire cloth or a powder metallurgy structure.

4. The siphon-type heat dissipation device according to claim 1, wherein the heat source comprises a heat transfer surface, and the heat transfer surface is attached on the first external surface or the second external surface along an attaching direction, wherein the attaching direction is perpendicular to the gravity direction.

5. The siphon-type heat dissipation device according to claim 1, wherein the heat source comprises a heat conduction substrate, and the heat conduction substrate is attached on the first external surface or the second external surface.

6. The siphon-type heat dissipation device according to claim 5, wherein the heat conduction substrate is attached on the first external surface or the second external surface along an attaching direction, wherein the attaching direction is perpendicular to the gravity direction.

7. The siphon-type heat dissipation device according to claim 1, further comprising a heat dissipation enhancement element, wherein the heat dissipation enhancement element is disposed on the first external surface and/or the second external surface and aligned with the upper portion of the accommodation space.

8. The siphon-type heat dissipation device according to claim 7, wherein the heat dissipation enhancement element is a fin-type heat sink, a fan or a heat pipe.

9. The siphon-type heat dissipation device according to claim 1, further comprising a supporting structure, wherein the supporting structure is disposed within the accommodation space and contacted with the first inner surface and the second inner surface.

10. The siphon-type heat dissipation device according to claim 9, wherein the supporting structure is protruded from the second inner surface of the second plate body toward the first plate body and connected with the first inner surface of the first plate body.

11. The siphon-type heat dissipation device according to claim 9, wherein the supporting structure is a wavy plate, wherein the wavy plate is disposed within the accommodation space and connected with the first inner surface and the second inner surface.

12. The siphon-type heat dissipation device according to claim 1, wherein the first plate body and the second plate body are made of different materials, and the first plate body and the second plate body are made of copper, aluminum or stainless steel.

13. The siphon-type heat dissipation device according to claim 1, wherein the heat source is a light source selected from a light emitting diode, a light bar or a light bulb.

14. The siphon-type heat dissipation device according to claim 1, wherein a volume of the working liquid accounts for 50% to 98% of a capacity of the accommodation space.

15. A display device, comprising:
a display panel;
a siphon-type heat dissipation device located near the display panel and comprising a first inner surface, a second inner surface and a working liquid, wherein the first inner surface and the second inner surface are opposed to and separated from each other, an accommodation space is formed between the first inner surface and the second inner surface, the accommodation space comprises an upper portion and a lower portion, and the working liquid is contained within the accommodation space and accumulated in the lower portion of the accommodation space along a gravity direction; and
a heat source arranged between the display panel and the siphon-type heat dissipation device, attached on the siphon-type heat dissipation device, and aligned with the lower portion of the accommodation space, wherein the heat source generates a light beam and a heat energy, and an image is shown on the display panel when the light beam is projected to the display panel, wherein after the heat energy is transferred into the accommodation space through the siphon-type heat dissipation device, the heat energy is absorbed by the working liquid, so that a portion of the working liquid is vaporized into a working vapor, wherein after the working vapor ascends to the upper portion of the accommodation space, the heat energy is dissipated to surroundings, the working vapor is condensed and changed into the working liquid, and the working liquid contacts with the first inner surface and the second inner surface and flows back to the lower portion of the accommodation space along the gravity direction.

16. The display device according to claim 15, wherein the siphon-type heat dissipation device is in parallel with the display panel.

17. The display device according to claim 15, wherein the siphon-type heat dissipation device further comprises a boiling enhancement structure, wherein the boiling enhancement structure is disposed within the lower portion of the accommodation space and immersed in the working liquid, wherein when the heat energy is transferred to the working liquid within the lower portion of the accommodation space through the boiling enhancement structure, the heat energy is absorbed by the working liquid, so that the working liquid is vaporized into the working vapor and the working vapor ascends to the upper portion of the accommodation space.

18. The display device according to claim 17, wherein the boiling enhancement structure is contacted with the first inner surface and/or the second inner surface, and the boiling enhancement structure is selected from a metallic foam structure, a woven wire cloth or a powder metallurgy structure.

19. The display device according to claim 15, wherein the siphon-type heat dissipation device further comprises a first external surface and a second external surface, wherein the heat source is attached on the first external surface or the second external surface, and the heat energy is transferred into the accommodation space through the first external surface or the second external surface.

20. The display device according to claim 19, wherein the siphon-type heat dissipation device further comprises a heat dissipation enhancement element, wherein the heat dissipation enhancement element is disposed on the first external surface and/or the second external surface and aligned with the upper portion of the accommodation space.

21. The display device according to claim 20, wherein the heat dissipation enhancement element is a fin-type heat sink, a fan or a heat pipe.

22. The display device according to claim 19, wherein the heat source comprises a heat transfer surface, and the heat transfer surface is attached on the first external surface or the second external surface along an attaching direction, wherein the attaching direction is perpendicular to the gravity direction.

23. The display device according to claim 19, wherein the heat source comprises a heat conduction substrate, and the heat conduction substrate is attached on the first external surface or the second external surface along an attaching direction, wherein the attaching direction is perpendicular to the gravity direction.

24. The display device according to claim 15, wherein the siphon-type heat dissipation device further comprises a supporting structure, wherein the supporting structure is disposed within the accommodation space and contacted with the first inner surface and the second inner surface.

25. The display device according to claim 24, wherein the supporting structure is protruded from the second inner surface toward the first inner surface and connected with the first inner surface.

26. The display device according to claim 24, wherein the supporting structure is a wavy plate, wherein the wavy plate is disposed within the accommodation space and connected with the first inner surface and the second inner surface.

27. The display device according to claim 15, wherein the siphon-type heat dissipation device further comprises a first plate body and a second plate body, wherein the first inner surface is formed on the first plate body, the second inner surface is formed on the second plate body, and the first plate body and the second plate body are partially attached on each other, so that the accommodation space is formed between the first inner surface and the second inner surface, wherein the first plate body and the second plate body are made of different materials, and the first plate body and the second plate body are made of copper, aluminum or stainless steel.

28. The display device according to claim 15, wherein the heat source is a light source selected from a light emitting diode, a light bar or a light bulb.

29. The display device according to claim 15, wherein a volume of the working liquid accounts for 50% to 98% of a capacity of the accommodation space.
